(19) United States
(12) Patent Application Publication
(10) Pub. No.: US 2026/0343776 A1
(43) Pub. Date: Oct. 29, 2026

(54) BACKUP POWER SUPPLY PATH FOR INVERTER SYSTEM CIRCUITRY

(71) Applicant: Rivian IP Holdings, LLC, Irvine, CA (US)

(72) Inventors: Seunghoon JEONG, La Mirada, CA (US); Juan LOPEZ, Wildomar, CA (US); Young DOO, La Palma, CA (US); Yochan SON, Rancho Palos Verdes, CA (US); Thomas Hahn KIM, Granada Hills, CA (US)

(21) Appl. No.: 19/193,827

(22) Filed: Apr. 29, 2025

(51) Int. Cl. H05K 7/14; H05K 1/02; H05K 1/14

(52) U.S. Cl. CPC H05K 7/14329; H05K 1/0201; H05K 1/144

(57) ABSTRACT

In one aspect, an inverter system includes a plurality of power modules disposed within a housing, a plurality of busbars disposed within the housing and connected with the plurality of power modules, and a printed circuit board assembly (PCBA) disposed within and connected to the housing. The PCBA includes control circuitry connected to a first power supply path and configured to control operation of the plurality of power modules. The inverter system further includes a second power supply path for the control circuitry, the second power supply path comprising a plurality of compliant contacts extending between the plurality of busbars and a first surface of the PCBA.

### INTRODUCTION

The present disclosure relates to techniques for assembling an inverter system having multiple power supply paths for control circuitry.

### SUMMARY

In one aspect, an inverter system includes a plurality of power modules disposed within a housing, a plurality of busbars disposed within the housing and connected with the plurality of power modules, and a printed circuit board assembly (PCBA) disposed within and connected to the housing. The PCBA includes control circuitry connected to a first power supply path and configured to control operation of the plurality of power modules. The inverter system further includes a second power supply path for the control circuitry, the second power supply path comprising a plurality of compliant contacts extending between the plurality of busbars and a first surface of the PCBA.

In another aspect, a method includes disposing a plurality of power modules within a housing. The plurality of power modules are connected with a plurality of busbars disposed within the housing. The method further includes connecting a printed circuit board assembly (PCBA) to the housing. The PCBA includes control circuitry connected to a first power supply path and configured to control operation of the plurality of power modules. Connecting the PCBA to the housing includes contacting a plurality of compliant contacts between a first surface of the PCBA and the plurality of busbars to form a second power supply path for the control circuitry.

### BRIEF DESCRIPTION OF THE DRAWINGS

FIG. 1A illustrates an example vehicle in accordance with certain embodiments.

FIG. 1B illustrates a chassis of a vehicle in accordance with certain embodiments.

FIG. 2A is a schematic block diagram of components of a vehicle in accordance with certain embodiments.

FIG. 2B is a schematic block diagram of alternative components of a vehicle in accordance with certain embodiments.

FIG. 3 is schematic block diagram illustrating power electronics of a vehicle in accordance with certain embodiments.

FIG. 4A is an exploded view of an example inverter system in accordance with certain embodiments.

FIG. 4B is a perspective view of a partial assembly of an example inverter system in accordance with certain embodiments.

FIG. 4C is a magnified perspective view of the partial assembly of FIG. 4B in accordance with certain embodiments.

FIG. 5 is a section view of an example shield bracket connected to a printed circuit board assembly (PCBA) using a spring-loaded tab, in accordance with certain embodiments.

FIGS. 6-8 are section views of an example shield bracket connected to a PCBA using one or more tabs with one or more deformable portions, in accordance with certain embodiments.

FIG. 9 is an exemplary method of assembling a inverter system in accordance with certain embodiments.

### DETAILED DESCRIPTION

An inverter system for a vehicle is assembled with multiple power supply paths for control circuitry. In one aspect, the inverter system includes a plurality of power modules disposed within a housing, a plurality of busbars disposed within the housing and connected with the plurality of power modules, and a printed circuit board assembly (PCBA) disposed within and connected to the housing. The PCBA includes control circuitry connected to a first power supply path and configured to control operation of the plurality of power modules. The inverter system further includes a second power supply path for the control circuitry, the second power supply path comprising a plurality of compliant contacts extending between the plurality of busbars and a first surface of the PCBA.

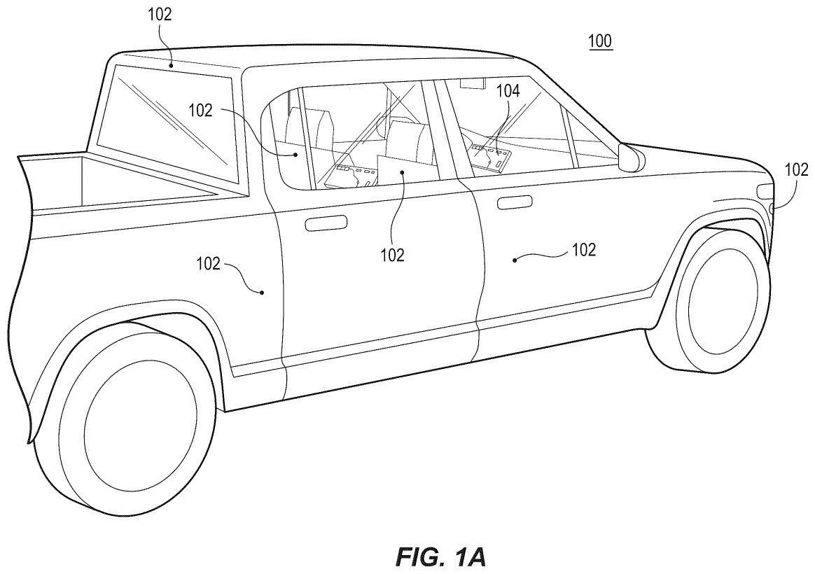

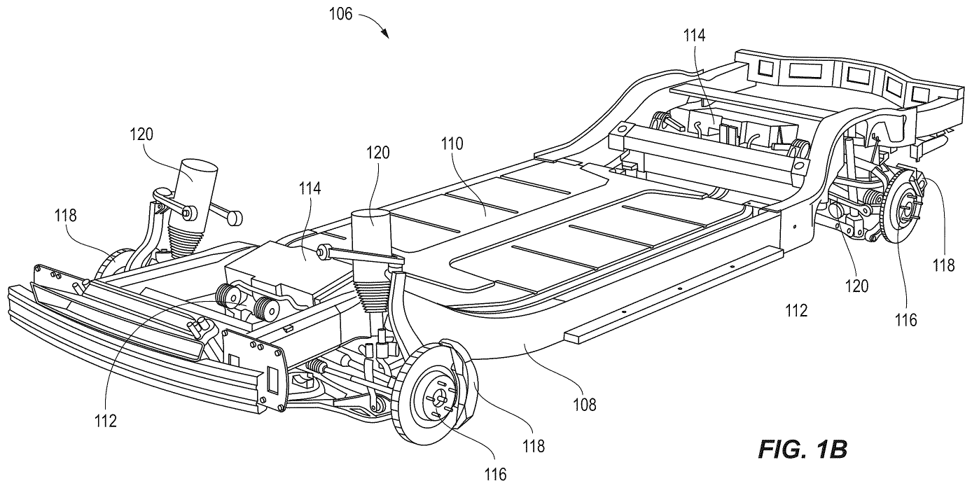

FIG. 1A illustrates an example vehicle 100. As seen in FIG. 1A, the vehicle 100 has multiple exterior cameras 102 and one or more front displays 104. Each of these exterior cameras 102 may capture a particular view or perspective on the outside of the vehicle 100. The images or videos captured by the exterior cameras 102 may then be presented on one or more displays in the vehicle 100, such as the one or more front displays 104, for viewing by a driver.

Referring to FIG. 1B, the vehicle 100 may include a chassis 106 including a frame 108 providing a primary structural member of the vehicle 100. The frame 108 may be formed of one or more beams or other structural members or may be integrated with the body of the vehicle (i.e., unibody construction).

In embodiments where the vehicle 100 is a battery electric vehicle (BEV) or possibly a hybrid vehicle, a large battery 110 is mounted to the chassis 106 and may occupy a substantial (e.g., at least 80 percent) of an area within the frame 108. For example, the battery 110 may store from 100 to 200 kilowatt hours (kWh). The battery 110 may be a lithium-ion battery or other type of rechargeable battery. The battery may be substantially planar in shape.

Power from the battery 110 may be supplied to one or more drive units 112. Each drive unit 112 may be formed of an electric motor and possibly a gear reduction drive. In some embodiments, there is a single drive unit 112 driving either the front wheels or the rear wheels of the vehicle 100. In another embodiment, there are two drive units 112, each driving either the front wheels or the rear wheels of the vehicle 100. In yet another embodiment, there are four drive units 112, each drive unit 112 driving one of four wheels of the vehicle 100.

Power from the battery 110 may be supplied to the drive units 112 by an inverter system 114. The inverter system 114 may include inverters configured to convert direct current (DC) from the battery 110 into alternating current (AC) supplied to the motors of the drive units 112. In some embodiments, the inverter system 114 is implemented to include a plurality of power modules.

The drive units 112 are coupled to two or more hubs 116 to which wheels may mount. Each hub 116 includes a corresponding brake 118, such as the illustrated disc brakes. The drive units 112 or other component may also provide regenerative braking. Each hub 116 is further coupled to the frame 108 by a suspension 120. The suspension 120 may include metal or pneumatic springs for absorbing impacts. The suspension 120 may be implemented as a pneumatic or hydraulic suspension capable of adjusting a ride height of the chassis 106 relative to a support surface. The suspension 120 may include a damper with the properties of the damper being either fixed or adjustable electronically.

In the embodiment of FIG. 1B and in the discussion below, the vehicle 100 is a battery electric vehicle. However, the systems and methods disclosed herein may be used for any type of vehicle, including vehicles powered by an internal combustion engine (ICE), hybrid drivetrain, hydrogen fuel cell drivetrain, or other type of drivetrain that requires heating in preparation for use, such as diesel engines.

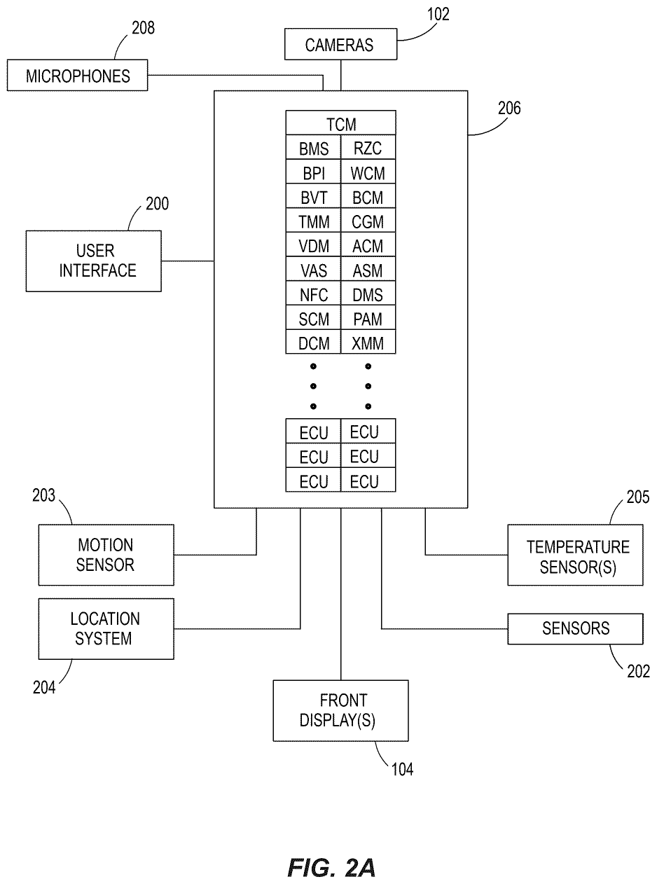

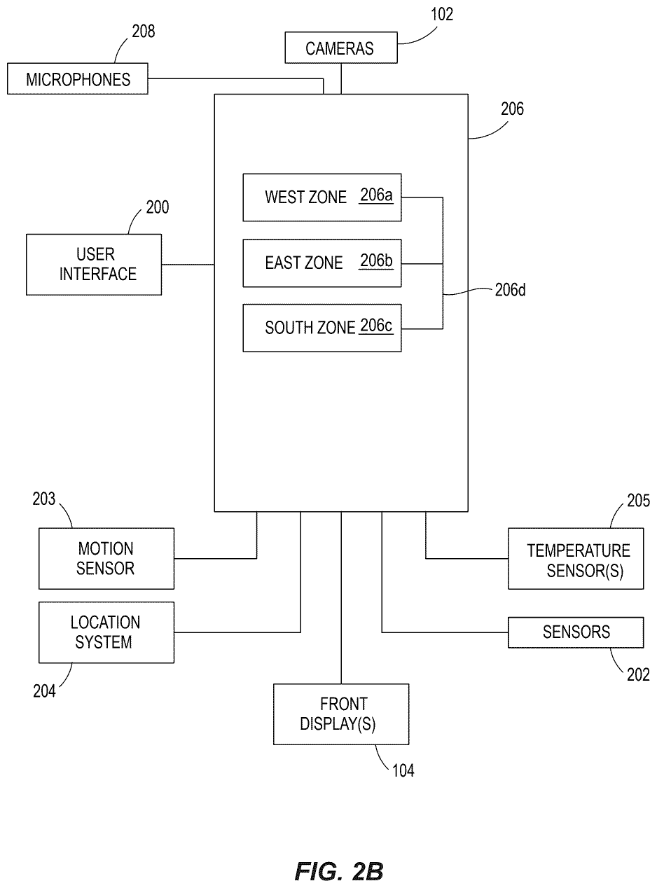

FIG. 2A illustrates example components of the vehicle 100 of FIG. 1A. As shown in FIG. 2A, the vehicle 100 includes the cameras 102, the one or more front displays 104, a user interface 200, one or more sensors 202, a motion sensor 203, and a location system 204. The one or more sensors 202 may include ultrasonic sensors, radio detection and ranging (RADAR) sensors, light detection and ranging (LIDAR) sensors, or other types of sensors. The location system 204 may be implemented as a global positioning system (GPS) receiver. The user interface 200 allows a user, such as a driver or passenger in the vehicle 100, to provide input.

The components of the vehicle 100 may include one or more temperature sensors 205. The temperature sensors 205 may include sensors configured to sense an ambient air temperature, temperature of the battery 110, temperature of the inverter system 114, temperature of each drive unit 112 and/or each motor of each drive unit 112, or the temperature of any other component of the vehicle 100.

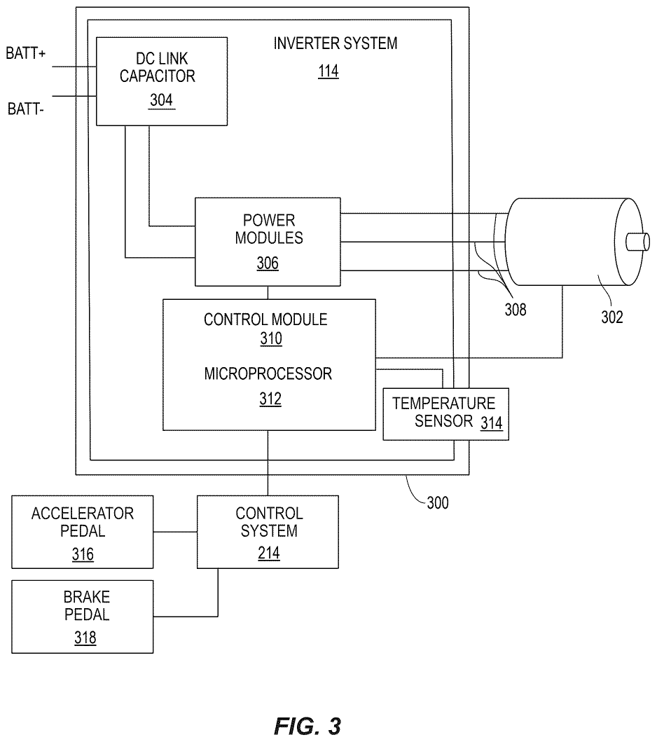

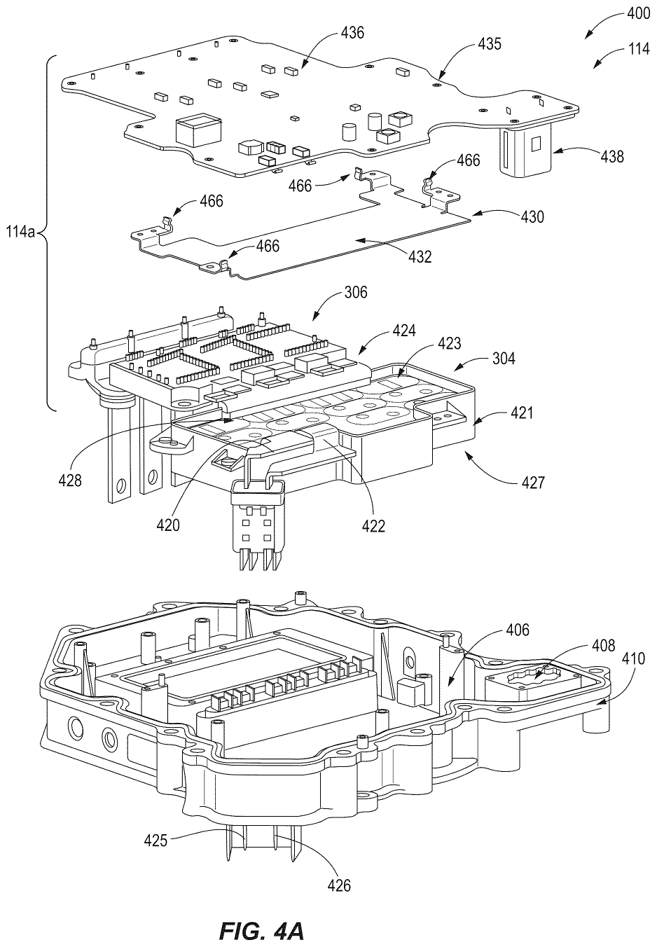

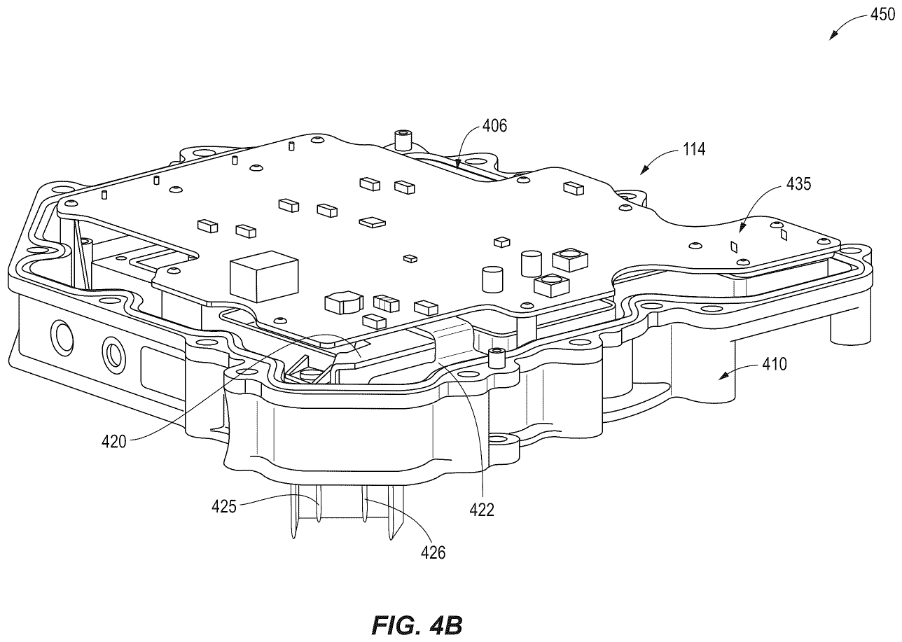

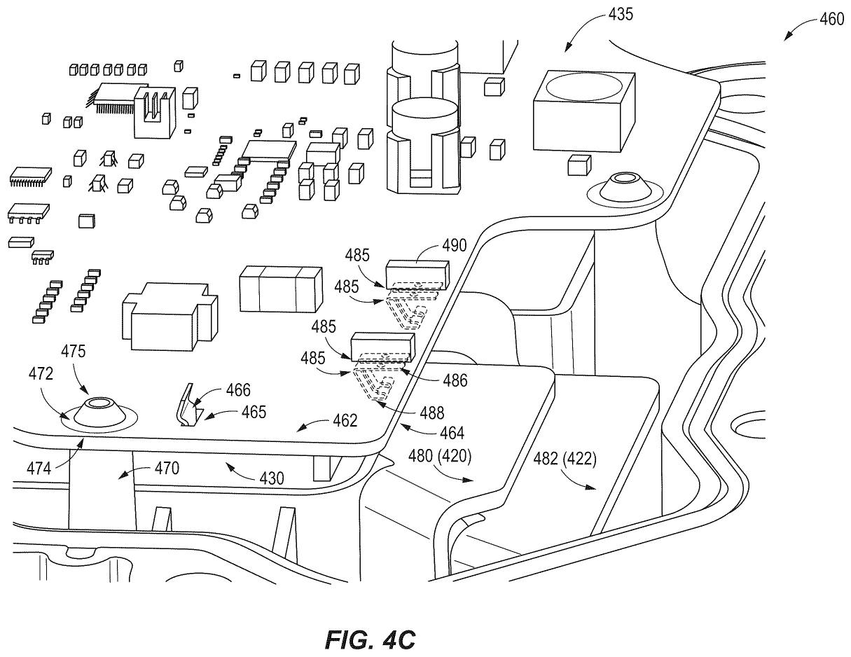

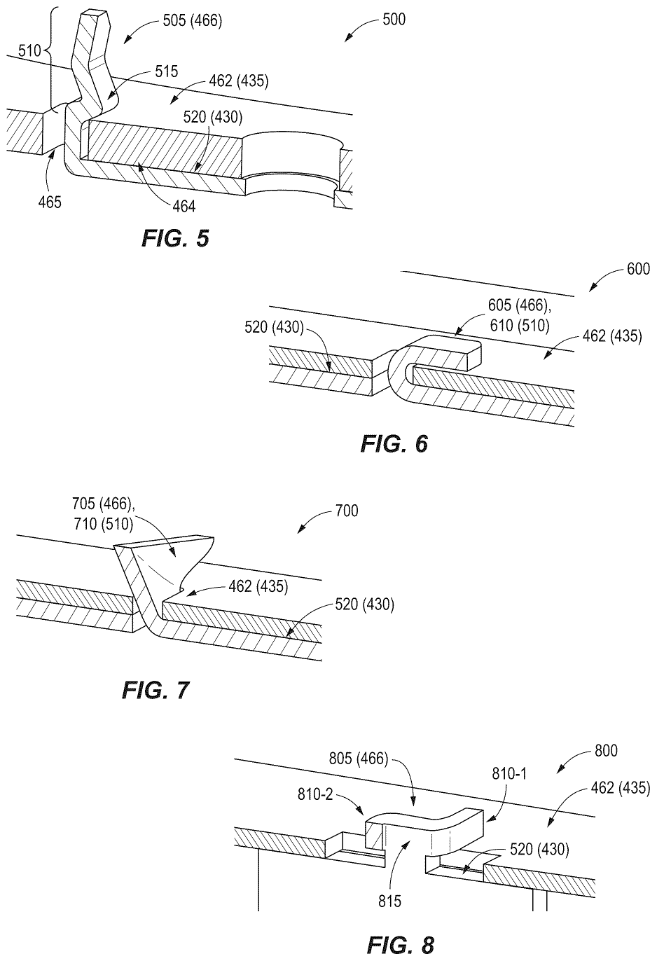

A control system 206 executes instructions to perform at least some of the actions or functions of the vehicle 100, including the functions described in relation to FIGS. 4 and 5. For example, as shown in FIG. 2, the control system 206 may include one or more electronic control units (ECUs) configured to perform at least some of the actions or functions of the vehicle 100, including the functions described in relation to FIGS. 3A to 3E. In certain embodiments, each of the ECUs is dedicated to a specific set of functions. Each ECU may be a computer system and each ECU may include functionality described below in relation to FIGS. 3A to 3E.

Certain features of the embodiments described herein may be controlled by a Telematics Control Module (TCM) ECU. The TCM ECU may provide a wireless vehicle communication gateway to support functionality such as, by way of example and not limitation, over-the-air (OTA) software updates, communication between the vehicle and the internet, communication between the vehicle and a computing device, in-vehicle navigation, vehicle-to-vehicle communication, communication between the vehicle and landscape features (e.g., automated toll road sensors, automated toll gates, power dispensers at charging stations), or automated calling functionality.

Certain features of the embodiments described herein may be controlled by a Central Gateway Module (CGM) ECU. The CGM ECU may serve as the vehicle's communications hub that connects and transfer data to and from the various ECUs, sensors, cameras, microphones, motors, displays, and other vehicle components. The CGM ECU may include a network switch that provides connectivity through Controller Area Network (CAN) ports, Local Interconnect Network (LIN) ports, and Ethernet ports. The CGM ECU may also serve as the master control over the different vehicle modes (e.g., road driving mode, parked mode, off-roading mode, tow mode, camping mode), and thereby control certain vehicle components related to placing the vehicle in one of the vehicle modes.

In various embodiments, the CGM ECU collects sensor signals from one or more sensors of vehicle 100. For example, the CGM ECU may collect data from cameras 102 and sensors 202.

The control system 206 may also include one or more additional ECUs, such as, by way of example and not limitation: a Vehicle Dynamics Module (VDM) ECU, an Experience Management Module (XMM) ECU, a Vehicle Access System (VAS) ECU, a Near-Field Communication (NFC) ECU, a Body Control Module (BCM) ECU, a Seat Control Module (SCM) ECU, a Door Control Module (DCM) ECU, a Rear Zone Control (RZC) ECU, an Autonomy Control Module (ACM) ECU, an Autonomous Safety Module (ASM) ECU, a Driver Monitoring System (DMS) ECU, and/or a Winch Control Module (WCM) ECU. If vehicle 100 is an electric vehicle, one or more ECUs may provide functionality related to the battery pack of the vehicle, such as a Battery Management System (BMS) ECU, a Battery Power Isolation (BPI) ECU, a Balancing Voltage Temperature (BVT) ECU, and/or a thermal Management Module (TMM) ECU. In various embodiments, the XMM ECU transmits data to the TCM ECU (e.g., via Ethernet, etc.). Additionally or alternatively, the XMM ECU may transmit other data (e.g., sound data from microphones 208, etc.) to the TCM ECU.

Referring to FIG. 2B, in some embodiments, the control system 206 may be implemented as a plurality of zonal controllers 206a, 206b, 206c. Each zonal controller 206a, 206b, 206c may control a subset of systems of the vehicle. The subset of systems controlled by each zonal controller 206a, 206b, 206c may be generally assigned based on location within the vehicle 100. For example, a west zonal controller 206a may control systems on a driver side of the vehicle 100, an east zonal controller 206b may control systems on a passenger side of the vehicle 100, and a south zonal controller 206c may control systems in a rear portion of the vehicle. Each zonal controller 206a, 206b, 206c may implement a portion of the functions ascribed to the ECUs of the control system 206 of FIG. 2A. The functions of the ECUs may be distributed among the zonal controller 206a, 206b, 206c such that only one zonal controller 206a, 206b, 206c implements the functions of each ECU. Alternatively, the functions of an ECU may be duplicated across multiple zonal controllers 206a, 206b, 206c, each zonal performing the functions of the ECU for the portion of the vehicle to which that zonal controller 206a, 206b, 206c is assigned.

The zonal controllers 206a, 206b, 206c may be connected to one another by a network 206d, such as an Ethernet network, controller area network (CAN), or other type of network.

Referring now to FIG. 3, the inverter system 114 may be contained within a housing 300, which may be formed of any suitable materials such as aluminum or steel. The inverter system 114 includes a plurality of components configured to convert direct current (DC) power from the battery 110 into alternating current (AC) power, such as three-phase AC, that is supplied to one or more motors 302 of the drive unit(s) 112 corresponding to the inverter system 114.

In some embodiments, the inverter system 114 receives power from the battery 110 through a DC link capacitor 304 that is connected between the positive and negative terminals (BATT+, BATT−) of the battery 110, and functions to smooth current received from the battery 110 as part of the process by which the DC power from the battery 110 is converted to an approximately sinusoidal AC waveform. The DC link capacitor 304 may further function to dampen any voltage spikes. The DC link capacitor 304 may be disposed within the housing 300 or may be external to the housing 300. Further, the DC link capacitor 304 may provide smoothed DC power to a single inverter system 114 or may be shared by multiple inverter systems 114. Although not shown, other filtering circuitry at the DC link is also contemplated (e.g., a DC choke), and may be disposed within the housing 300 and/or external thereto.

In some embodiments, the inverter system 114 includes a plurality of power modules 306 that are connected to the outputs of the DC link capacitor 304. The plurality of power modules 306 include a plurality of switches that are selectively opened and closed to cause transmission of current to the outputs of the inverter system 114 with desired AC electrical characteristics (e.g., waveform, voltage, current, frequency, phase, and so forth) for driving the one or more motors 302. For example, the plurality of power modules 306 may output three-phase current over transmission lines 308 that connect the plurality of power modules 306 to the motor 302. Although not shown, filtering circuitry may be included between the plurality of power modules 306 and the transmission lines 308.

The opening and closing of the plurality of power modules 306 is controlled by a control module 310 comprising control circuitry. In some embodiments, the control circuitry is included in a printed circuit board assembly (PCBA) and comprises various electronic components that generate the control signals for the plurality of power modules 306. In some embodiments, the inverter system 114 powers two drive units 112 and includes separate PCBAs for supplying current to the motors 302 of the separate drive units 112. In other embodiments, the inverter system 114 powers a single drive unit 112.

In some embodiments, the control module 310 includes a microprocessor 312 programmed to control operation of the control module 310 and the plurality of power modules 306. The microprocessor 312 may be embodied as a silicon chip mounted to the PCBA of the control module 310. In some embodiments, a temperature sensor 314 provides temperature measurements to the control module 310. In some embodiments, the control module 310 controls the operation of the plurality of power modules 306 based in part on temperature measurements obtained by the temperature sensor 314. In some embodiments, the temperature sensor 314 is connected to a busbar that is connected to the DC link capacitor 304, and the temperature measurements may be used by the control module 310 to derate the output from the plurality of power modules 306 from a nominal output.

The control module 310 is connected to the control system 214 and, in some embodiments, implements instructions from the control system 214 to control current supplied to the motor 302 and/or to cause the motor 302 to produce regenerative current. The control system 214 may generate such instructions according to an automated driving algorithm (e.g., automatic cruise control), safety algorithm (e.g., traction control, stability control, automated emergency braking), and/or in response to inputs from a driver by way of an accelerator pedal 316 and/or brake pedal 318.

FIGS. 4A, 4B, and 4C illustrate an example implementation of the inverter system 114. More specifically, FIG. 4A is an exploded view 400 of the inverter system 114, FIG. 4B is a perspective view 450 of a partial assembly of the inverter system 114, and FIG. 4C is a magnified view 460 of a portion of the partial assembly.

In the illustrated embodiment representing one example implementation of the housing 300, a lower housing 410 together with an upper housing (not shown) define an interior volume 406. When the upper housing is secured to the lower housing 410, e.g., along a periphery of the lower housing 410, the interior volume 406 may be sealed to prevent ingress of air, water, or contaminants. The interior volume 406 contains the DC link capacitor 304 and a single set of power electronics 114a. As used herein, “power electronics” refers to a subset of components of the inverter system 114 that may be duplicated and used to drive separate motors 302. For example, the power electronics 114a may include a first plurality of power modules 306 and a control module 310 (including a microprocessor 312) configured to control operation of the first plurality of power modules 306 as described above. In the illustrated embodiment, a single DC link capacitor 304 is connected to the power electronics 114a. However, in other embodiments, the DC link capacitor 304 may be shared by different power electronics of the inverter system 114.

The DC link capacitor 304 includes a housing 421 that houses a plurality of capacitor units 428 disposed between a negative capacitor busbar layer 423 and a positive capacitor busbar layer 427 (not visible; beneath the plurality of capacitor units 428). When the inverter system 114 is assembled, the housing 421 is disposed within the interior volume 406 of the housing 300. A plurality of busbars 420, 422 (also referred to as a “negative busbar 420” and a “positive busbar 422”) are disposed within the interior volume 406 near a periphery thereof, and extend from respective input terminals 425, 426 of the inverter system 114. As shown, the negative busbar 420 extends into the housing 421 to connect a negative input terminal 425 to the negative capacitor busbar layer 423, and the positive busbar 422 extends into the housing 421 to connect a positive input terminal 426 to the positive capacitor busbar layer 427. The plurality of busbars 420, 422 may have any suitable geometry, which may include routing around support structures of the housing 300 and other components within the interior volume 406. In turn, the negative input terminal 425 may be connected to the negative terminal BATT− of the battery 110 and the positive input terminal 426 may be connected to the positive terminal BATT+ of the battery 110 (e.g., through a connectorized cable), although other implementations may reverse the connections and/or include greater or fewer terminals.

The negative capacitor busbar layer 423 may be implemented as a sheet, flat surface, plane, area, region, etc., of conductive material, such as copper, that electrically connects the negative terminals of the plurality of capacitor units to the negative input terminal 425. Similarly, the positive capacitor busbar layer 427 may be implemented as a sheet, flat surface, plane, area, region, etc. of conductive material, such as copper, that electrically connects the positive terminals of the plurality of capacitor units to the positive input terminal 426. Although not shown, insulation may be provided between the respective input terminals 425, 426, the respective busbars 420, 422, the respective capacitor busbar layers 423, 427, various components and the housings 300, 421, and so forth to provide electrical isolation.

The power electronics 114a connect to a plurality of output terminals 424 of the DC link capacitor 304. For example, in the illustrated embodiment, the plurality of output terminals 424 includes three positive output terminals interleaved with three negative output terminals. The circuitry for each phase of power supplied by the power electronics 114a is connected with one positive output terminal and one negative output terminal. The plurality of output terminals 424 may be secured to the corresponding contacts on the power electronics 114a using any suitable techniques, such as screws, welds, or other fastening approach.

The power electronics 114a are supplied DC power through the plurality of output terminals 424 and operate to convert the DC power to AC power. The power electronics 114a further include output terminals that each supply AC power to a different motor 302, e.g., left and right front motors 302 of a front drive unit 112 or left and right front motors 302 of a rear drive unit 112.

As discussed above, the PCBA 435 includes control circuitry 436 (e.g., forming part of the power electronics 114a and the control module 310) that comprises various electronic components that generate the control signals for operating the plurality of power modules 306. The control circuitry 436 may be further connected to the control system 214 and communicate therewith. The PCBA 435 includes a connector 438 providing external signal and/or power connections for the control circuitry 436 and/or other circuitry of the PCBA 435. The connector 438 may have any suitable implementation (e.g., a plurality of male or female connector pins) and in some embodiments extends through an opening 408 formed through the lower housing 410. In some embodiments, the PCBA 435 is supplied low-voltage DC power (e.g., between about 3 volts and about 24 volts) through the connector 438, forming a first (or “primary”) power supply path for the control circuitry 436.

A shield bracket 430 is disposed between the DC link capacitor 304 (and more specifically, the negative capacitor busbar layer 423) and at least a portion of the PCBA 435. The shield bracket 430 operates to protect the circuitry of the PCBA 435 from electromagnetic interference to promote consistent operation of the circuitry and reduce the likelihood of fault conditions. The shield bracket 430 includes a substantially planar body 432 and one or more retaining features 466 extending outward from the body 432. As used herein, “substantially planar” contemplates strictly planar implementations (e.g., having a uniform thickness) of the shield bracket, non-uniform thicknesses (e.g., thickness changes, openings, recesses, protrusions), contouring that averages to being planar (e.g., corrugations), and so forth.

In some embodiments, the one or more retaining features 466 extend outward in a substantially orthogonal direction from the plane of the body 432, and may include further contouring. Four retaining features 466 are shown, but different numbers are also contemplated. The PCBA 435 includes a plurality of openings that are aligned with the plurality of retaining features 466, such that a portion of each retaining feature 466 extends through a respective opening to connect the shield bracket 430 to the PCBA 435. In some embodiments, the portion of each retaining feature 466 extends in a substantially orthogonal direction from the plane of the body 432 to extend through the respective opening.

Referring to the magnified view 460 of FIG. 4C, the PCBA 435 defines a first surface (or “upper surface”) 462, an opposing second surface (or “lower surface”) 464, and one or more openings 465 extending through the PCBA 435 (e.g., between the upper surface 462 and the lower surface 464). The shield bracket 430 is connected to the PCBA 435 using the one or more retaining features 466 of the shield bracket 430, which extend through the one or more openings 465. Several example implementations of the one or more retaining features 466 are discussed below with respect to FIGS. 5-8. For example, the one or more retaining features 466 may be implemented as spring-loaded tabs or tabs having deformable portions.

When the shield bracket 430 is connected to the PCBA 435, the shield bracket 430 is disposed at or near the lower surface 464 of the PCBA 435. A first portion of the shield bracket 430 (e.g., the plurality of retaining features 466) may directly contact the PCBA 435, and a second portion of the shield bracket (e.g., the body 432) may be offset from the PCBA 435.

The subassembly of the connected PCBA 435 and shield bracket 430 is connected to the housing 300. In some embodiments, the lower housing 410 defines one or more bosses 470 (or raised interfaces) that are aligned with a corresponding one or more openings 472 that extend through the PCBA 435. In some embodiments, one or more openings 474 extend through the shield bracket 430 and are aligned with the one or more openings 472. One or more fasteners 475 extend through a corresponding one or more openings 472 (and in some cases, through the one or more openings 474) and into the corresponding one or more bosses 470. For example, the one or more fasteners 475 may be implemented as screws that engage internal threads of the one or more bosses 470 to fasten the subassembly to the lower housing 410.

By connecting the shield bracket 430 to the PCBA 435 using the plurality of retaining features 466, the shield bracket 430 may be connected to the housing 300 without requiring fasteners to separately attach the shield bracket 430 to the housing 300. As a result, the shield bracket 430 may have a thinner implementation, and in some embodiments may be formed of sheet metal. Using less material, the shield bracket 430 may be lighter and more cost-effective than a die-cast shield bracket. Further, attachment of the shield bracket 430 in this manner allows the inverter system 114 to be assembled with fewer fastener joints, reducing the likelihood of errors during assembly (e.g., torque out of specification) and making the inverter system 114 more reliable.

The inverter system 114 further comprises a plurality of compliant contacts 485 extending between the lower surface 464 of the PCBA 435 and the plurality of busbars 420, 422. More specifically, the plurality of compliant contacts 485 contact conductive regions disposed at the lower surface 464 and respective top surfaces 480, 482 of the plurality of busbars 420, 422.

In some embodiments, the plurality of compliant contacts 485 comprise a plurality of contact springs, where one or more first contact springs contact a first busbar, and one or more second contact springs contact a second busbar. As shown, two (2) first contact springs contact the negative busbar 420, and two (2) second contact springs contact the positive busbar 422, although different numbers of contact springs are also contemplated.

In some embodiments, the plurality of contact springs are surface-mount devices that are rigidly connected to the lower surface 464 of the PCBA 435. As shown, a base 486 of each contact spring is attached to the lower surface 464, and an arm 488 of the contact spring extends from the base 486 and contacts the top surface 480, 482 of the respective busbar 420, 422. Other arrangements and/or types of the plurality of compliant contacts 485 are also contemplated, such as contact springs rigidly connected to the busbars 420, 422 and extending to the lower surface 464, pogo (spring-loaded) pins, and so forth.

In some embodiments, the PCBA 435 further comprises power conditioning circuitry (not shown) that connects to the busbars 420, 422 through the plurality of compliant contacts 485. The power conditioning circuitry may have any suitable implementation, such as including a DC converter that converts the higher-voltage DC power carried by the busbars 420, 422 to the low-voltage DC power (e.g., between about 3 volts and about 24 volts) that is used for the control circuitry 436. In this way, the plurality of compliant contacts 485 and the power conditioning circuitry (and optionally, any switching circuitry that selectively connects the power conditioning circuity with the control circuitry 436) form a second (or “backup”) power supply path for the control circuitry 436.

By providing the second power supply path, DC power may be provided to the control circuitry 436 to operate the inverter system 114 even in cases where the low-voltage DC power is unavailable from the first power supply path (e.g., a fault occurring external to the inverter system 114). In some embodiments, due to the second power supply path, the control circuitry 436 is consistently able to, responsive to detecting a loss of low-voltage DC power from the first power supply path, transition to a safe state (e.g., reduced operation) within a predetermined amount of time, e.g., 100 milliseconds. This responsiveness enables continued safe operation of the inverter system 114 (and the associated vehicle).

Beneficially, using the plurality of compliant contacts 485 to connect to the busbars 420, 422 provides a more cost-effective implementation than a wiring harness, reducing installation time and the expense of additional parts. Further, assembly of the inverter system 114 is simplified by forgoing a wiring harness, reducing a number of potential failure points and increasing the overall reliability of the inverter system 114.

In some embodiments, a temperature sensor 490 is connected to a first busbar 422 (e.g., through one or more of the plurality of compliant contacts 485) and the control circuitry 436 is configured to control the operation of the plurality of power modules 306 based in part on temperature measurements of the first busbar 422. For example, the amount of current generated by the plurality of power modules 306 and delivered to the motors 302 may be reduced when the first busbar 422 experiences high temperature conditions (e.g., desert driving, towing). The temperature sensor 490 may have any suitable implementation, such as a thermistor, thermocouple, or semiconductor-based sensor. As shown, temperature sensor 490 is connected to the positive busbar 422, although other implementations may have the temperature sensor 490 connected to the negative busbar 420.

Acquiring the temperature measurements of the first busbar 422 using conductive connections allows faster, more accurate temperature measurements than other techniques such as three-phase current sensing, which is affected by convection (ambient air) and delays due to performing calculations. Further, temperature spikes may be predicted more accurately. The improved temperature measurements allow more responsive control of the inverter system 114 and the associated vehicle. For example, the plurality of control circuitry 436 may adjust (e.g., derate) the power output of the power modules 306 according to a temperature algorithm, and the improved temperature measurements allow more aggressive performance without unnecessary risk of damage to the motors 302, the power modules 306, and so forth.

FIG. 5 is a section view 500 of an example shield bracket 430 connected to the PCBA 435 using a spring-loaded tab 505, in accordance with certain embodiments. The features illustrated in the section view 500 may be used in conjunction with other embodiments.

In the section view 500, the one or more retaining features 466 comprise one or more spring-loaded tabs 505 extending substantially orthogonally to a plane of the body 432 of the shield bracket 430. When the spring-loaded tab 505 is elastically deformed (e.g., force applied by a finger of an installer, or by a tool), the spring-loaded tab 505 is received in the opening 465 and a portion 510 of the spring-loaded tab 505 extends through the opening 465 (e.g., beyond an upper surface 462 of the PCBA 435). The portion 510 is elastically biased to apply force to one or more surfaces of the PCBA 435, such as a perimeter of the opening 465 and/or the upper surface 462. In some embodiments, the spring-loaded tab 505 is contoured to form a projection 515 that contacts the upper surface 462 when the shield bracket 430 is connected to the PCBA 435. As shown, an upper surface 520 of the shield bracket 430 contacts the lower surface 464 of the PCBA 435. The projection 515 may be released from contacting the upper surface 462 by applying force to the portion 510 in a direction against the elastic bias.

FIG. 6 is a section view 600 of an example shield bracket 430 connected to the PCBA 435 using a tab 605 with a deformable portion 610, in accordance with certain embodiments. The features illustrated in the section view 600 may be used in conjunction with other embodiments.

In the section view 600, the one or more retaining features 466 comprise one or more tabs 605 extending substantially orthogonally to a plane of the body 432 of the shield bracket 430. The one or more tabs 605 have a deformable portion 610 extending beyond the one or more corresponding openings 465 of the PCBA 435. In some embodiments, the entire portion 510 that extends through the opening 465 forms the deformable portion 610. In other embodiments, some of the portion 510 forms the deformable portion 610 (e.g., a portion having reduced thickness or intentional weaknesses to encourage deformation). The deformable portion 610 may be plastically deformed during assembly in any suitable manner (e.g., bent or twisted by an installer or a tool) to retain the shield bracket 430 to the PCBA 435. In some embodiments, the deformable portion 610 contacts one or more surfaces of the PCBA 435, such as the upper surface 462. As shown in the section view 600, the deformable portion 610 is bent from a substantially orthogonal orientation relative to the upper surface 462, to a substantially parallel orientation to contact the upper surface 462.

In the section view 700 of FIG. 7, the one or more retaining features 466 comprise one or more tabs 705 extending substantially orthogonally to a plane of the body 432 of the shield bracket 430. The one or more tabs 705 have a deformable portion 710 corresponding to some or all of the portion 510 that extends through the opening 465. In some embodiments, the deformable portion 710 is twisted around a central axis with a substantially orthogonal (e.g., vertical) orientation relative to the upper surface 462, to a twisted orientation where some of the deformable portion 710 contacts the perimeter of the opening 465 and/or the upper surface 462 to limit and/or prevent relative movement of the shield bracket 430 and the PCBA 435. In other embodiments, the one or more tabs 705 includes a tab having a right-angle contour that extends through a corresponding right-angle opening 465. The deformable portion 710 may be deflected in any suitable direction(s) to contact the perimeter of the opening 465 and/or the upper surface 462 to limit and/or prevent relative movement of the shield bracket 430 and the PCBA 435.

In the section view 800 of FIG. 8, the one or more retaining features 466 comprise one or more tabs 805 extending substantially orthogonally to a plane of the body 432 of the shield bracket 430. The one or more tabs 805 have a central portion 815 disposed within the plane of the one or more tabs 805, and deformable portions 810-1, 810-2 disposed outward of the central portion 815 and that are deformable out of the plane of the one or more tabs 805 to contact the upper surface 462. In some embodiments, lateral slots are formed into the one or more tabs 805 to define the deformable portions 810-1, 810-2.

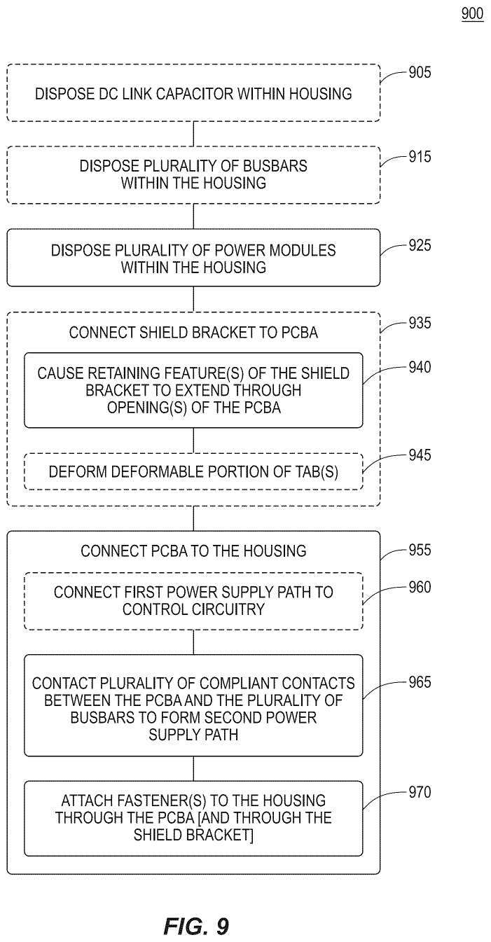

FIG. 9 is an exemplary method 900 of assembling an inverter system in accordance with certain embodiments. The features of the method 900 may be performed in conjunction with other embodiments, e.g., to assemble the inverter system 114 of FIG. 4A.

The method 900 begins at an optional block 905, where a DC link capacitor 304 is disposed within a housing 300 of the inverter system 114. In some embodiments, the DC link capacitor 304 includes its own housing 421 that is disposed within the housing 300 of the inverter system 114. At an optional block 915, a plurality of busbars 420, 422 are disposed within the housing 300. In some embodiments, the plurality of busbars 420, 422 extend from respective input terminals 425, 426 of the inverter system 114 and connect to respective capacitor busbar layers 423, 427. At block 925, a plurality of power modules are disposed within the housing 300.

At an optional block 935, a shield bracket 430 is connected to the PCBA 435. In some embodiments, connecting the shield bracket 430 to the PCBA 435 comprises (at block 940) causing retaining features 466 of the shield bracket 430 to extend through opening(s) 465 of the PCBA 435. In some embodiments, the retaining features 466 are elastically biased to contact one or more surfaces of the PCBA 435. In some embodiments, the retaining features 466 are implemented as tabs that extend through the openings 465, and connecting the shield bracket 430 to the PCBA 435 further comprises (at optional block 945) deforming deformable portion(s) of the tabs to contact the one or more surfaces of the PCBA 435.

At block 955, the PCBA 435 is connected to the housing 300. In some embodiments, connecting the PCBA 435 to the housing 300 comprises (at optional block 960) connecting a first power supply path to control circuitry 436 of the PCBA 435. In some embodiments, connecting the PCBA 435 to the housing 300 comprises (at block 965) contacting a plurality of compliant contacts between the PCBA 435 and the plurality of busbars 420, 422 to form a second power supply path. At block 970, one or more fasteners 475 are attached to the housing 300 through the PCBA 435 (and optionally, through the shield bracket 430). The method 900 ends following completion of block 955.

The descriptions of the various embodiments of the present disclosure have been presented for purposes of illustration. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

In the preceding, reference is made to embodiments presented in this disclosure. However, the scope of the present disclosure may exceed the specific described embodiments. Instead, any combination of the features and elements, whether related to different embodiments, is contemplated to implement and practice contemplated embodiments. Furthermore, although embodiments disclosed herein may achieve advantages over other possible solutions or over the prior art, the embodiments may achieve some advantages or no particular advantage. Thus, the aspects, features, embodiments and advantages discussed herein are merely illustrative.

Aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.”

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a one or more computer processing devices. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Certain types of storage devices that include these mediums include: diskette, hard disk, random access memory (RAM), read only memory (ROM), erasable programmable read only memory (EPROM or Flash memory), static random access memory (SRAM), compact disc read only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, refers to non-transitory storage rather than transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but the storage device remains non-transitory during these processes because the data remains non-transitory while stored.

While the foregoing is directed to embodiments of the present disclosure, other and further embodiments may be devised without departing from the basic scope thereof, and the scope thereof is determined by the claims that follow.

What is claimed is:

1. An inverter system comprising:
a plurality of power modules disposed within a housing;
a plurality of busbars disposed within the housing and connected with the plurality of power modules;
a printed circuit board assembly (PCBA) disposed within and connected to the housing, the PCBA comprising control circuitry connected to a first power supply path and configured to control operation of the plurality of power modules; and
a second power supply path for the control circuitry, the second power supply path comprising a plurality of compliant contacts extending between the plurality of busbars and a first surface of the PCBA.

2. The inverter system of claim 1, wherein:
the plurality of compliant contacts comprise a plurality of contact springs,
one or more first contact springs of the plurality of contact springs contact a first busbar of the plurality of busbars, and
one or more second contact springs of the plurality of contact springs contact a second busbar of the plurality of busbars.

3. The inverter system of claim 2, wherein the plurality of contact springs are surface-mount devices that are rigidly connected to the first surface of the PCBA.

4. The inverter system of claim 1, wherein the plurality of busbars extend from a plurality of input terminals of the inverter system.

5. The inverter system of claim 4, further comprising:
a direct current (DC) link capacitor connected between a first busbar of the plurality of busbars, and a second busbar of the plurality of busbars.

6. The inverter system of claim 1, further comprising:
a shield bracket comprising one or more retaining features configured to extend through one or more corresponding openings of the PCBA to connect the shield bracket to the PCBA.

7. The inverter system of claim 6, wherein the shield bracket is formed of sheet metal.

8. The inverter system of claim 6, wherein the one or more retaining features comprise one or more tabs having a deformable portion extending beyond the one or more corresponding openings of the PCBA.

9. The inverter system of claim 6, wherein the one or more retaining features comprise one or more spring-loaded tabs.

10. The inverter system of claim 9, wherein the one or more spring-loaded tabs comprise a projection configured to contact an opposing second surface of the PCBA when the shield bracket is connected to the PCBA.

11. The inverter system of claim 1, further comprising:
a temperature sensor connected to a first busbar of the plurality of busbars, wherein the control circuitry is configured to control the operation of the plurality of power modules based in part on temperature measurements of the first busbar.

12. A method comprising:
disposing a plurality of power modules within a housing, wherein the plurality of power modules are connected with a plurality of busbars disposed within the housing; and
connecting a printed circuit board assembly (PCBA) to the housing, wherein the PCBA comprises control circuitry connected to a first power supply path and configured to control operation of the plurality of power modules,
wherein connecting the PCBA to the housing comprises contacting a plurality of compliant contacts between a first surface of the PCBA and the plurality of busbars to form a second power supply path for the control circuitry.

13. The method of claim 12, wherein:
the plurality of compliant contacts comprise a plurality of contact springs,
one or more first contact springs of the plurality of contact springs contact a first busbar of the plurality of busbars, and
one or more second contact springs of the plurality of contact springs contact a second busbar of the plurality of busbars.

14. The method of claim 13, wherein the plurality of contact springs are surface-mount devices that are rigidly connected to the first surface of the PCBA.

15. The method of claim 12, further comprising:
connecting a shield bracket to the PCBA prior to connecting the PCBA to the housing,
wherein connecting the shield bracket to the PCBA comprises causing one or more retaining features of the shield bracket to extend through one or more corresponding openings of the PCBA.

16. The method of claim 15, wherein the shield bracket is formed of sheet metal.

17. The method of claim 15, wherein:
the one or more retaining features comprise one or more tabs having a deformable portion extending beyond the one or more corresponding openings of the PCBA, and
connecting the shield bracket to the PCBA further comprises deforming the deformable portion.

18. The method of claim 15, wherein the one or more retaining features comprise one or more spring-loaded tabs.

19. The method of claim 15, wherein connecting the PCBA to the housing comprises attaching one or more fasteners to the housing through the PCBA and through the shield bracket.

20. The method of claim 12, wherein:
a temperature sensor is connected to a first busbar of the plurality of busbars, and
the control circuitry is configured to control the operation of the plurality of power modules based in part on temperature measurements of the first busbar.
